(19) United States
(12) Patent Application Publication
(10) Pub. No.: US 2020/0303252 A1
(43) Pub. Date: Sep. 24, 2020

(54) METHOD OF FORMING METAL TRACES

(71) Applicant: Shanghai Huahong Grace Semiconductor Manufacturing Corporation, Shanghai (CN)

(72) Inventors: Yi ZHANG, Shanghai (CN); Pei XIAO, Shanghai (CN)

(73) Assignee: Shanghai Huahong Grace Semiconductor Manufacturing Corporation, Shanghai (CN)

(21) Appl. No.: 16/592,000

(22) Filed: Oct. 3, 2019

(30) Foreign Application Priority Data
Mar. 20, 2019 (CN) 201910210578.2

(51) Int. Cl. H01L 21/768; H01L 21/311

(52) U.S. Cl. CPC H01L 21/76895; H01L 21/31116; H01L 21/7685

(57) ABSTRACT

A method of forming metal traces is disclosed, including: forming a bottom anti-reflection coating (BARC) layer and a patterned photoresist layer both on a metal layer; trimming the patterned photoresist layer and concurrently etching away a partial thickness of the BARC layer; and etching the metal layer with the trimmed patterned photoresist layer as a mask to form the metal traces. According to the method, the BARC layer is etched concurrently with the trimming of the patterned photoresist layer, dispensing with the need for separate opening of the BARC layer, which may exert adverse impacts on the line width of the metal traces. Therefore, metal traces with a uniform line width can be obtained with a significantly reduced risk of metal bridging and higher manufacturing yield.

### CROSS-REFERENCE TO RELATED APPLICATION

This application claims the priority of Chinese patent application number 201910210578.2, filed on Mar. 20, 2019, the entire contents of which are incorporated herein by reference.

### TECHNICAL FIELD

The present invention relates to the fabrication of semiconductor device and, in particular, to a method of forming metal traces.

### BACKGROUND

During the fabrication of semiconductor devices, etching processes are employed primarily to chemically or physically remove the materials of various layers over semiconductor substrates to form desired patterns. Such layers include metal ones, which are usually etched and patterned to form metal traces.

Metal interconnects are indispensable for semiconductor devices. With the advancement of semiconductor device fabrication technology, metal traces contained in metal interconnects are increasingly shrinking in line width and space. However, at a certain limit of line width or space, e.g., smaller than 0.1 μm, it will be different for existing etching techniques to create satisfactory metal traces, and the actual resulting traces tend to be wider than desired, leaving spaces between them that are too narrow (e.g., smaller than 30 nm) to prevent line-to-line metal bridging. In worst cases, the whole metal interconnect may fail. Therefore, there is an urgent need in the art for an etching method capable of forming metal traces less suffering from metal bridging.

### SUMMARY OF THE INVENTION

The present invention seeks to overcome the problem of possible metal bridging between metal traces fabricated by existing etching techniques by presenting a method of forming metal traces.

To this end, the method includes providing a metal layer and forming a BARC layer on the metal layer; forming a patterned photoresist layer on the BARC layer; trimming the patterned photoresist layer and concurrently etching away a partial thickness of the BARC layer; and etching the metal layer with the trimmed patterned photoresist layer as a mask to form the metal traces.

Optionally, the metal layer may include a first metal barrier layer, an aluminum layer and a second metal barrier layer, which are stacked together sequentially, wherein the second metal barrier layer is closer to the BARC layer than the first metal barrier layer.

Optionally, each of the first and second metal barrier layers may be a Ti/TiN stacked layer.

Optionally, the method may further include forming a DARC layer disposed between the BARC layer and the metal layer.

Optionally, the BARC layer may be an organic or inorganic layer, while the DARC layer may be a SiO₂, SiON or SiN layer.

Optionally, the BARC layer may have a thickness ranging from 30 nm to 60 nm, while the DARC layer may have a thickness ranging from 20 nm to 50 nm.

Optionally, the patterned photoresist layer may be trimmed by a dry etching process.

Optionally, an etchant gas used in the dry etching process may include Cl₂ and BCL₃ and wherein a Cl₂/BCL₃ flow has a rate ratio between 0.5 and 5 and is performed at a radio frequency power level of 100-500 W and a bias voltage of 50-200 V.

Optionally, the etching of the BARC layer may include primary etching and over-etching following the primary etching.

Optionally, the primary etching may be accomplished by an etchant gas including Cl₂ and BCL₃ at a Cl₂/BCL₃ flow rate ratio between 1 and 5, an RF power level of 100-500 W and a bias voltage of 200-500 V.

Optionally, the over-etching may be accomplished by an etchant gas including Cl₂ and BCL₃ at a Cl₂/BCL₃ flow rate ratio between 1 and 5, an RF power level of 100-500 W and a bias voltage of 200-500 V.

In summary, the present invention provides a method of forming metal traces, including: forming a BARC layer and a patterned photoresist layer both on a metal layer; trimming the patterned photoresist layer and concurrently partially etching away the BARC layer; and etching the metal layer with the trimmed patterned photoresist layer as a mask to form the metal traces. According to the invention, the BARC layer is etched concurrently with the trimming of the patterned photoresist layer, dispensing with the need for separate opening of the BARC layer, which may exert adverse impacts on the line width of the metal traces. Therefore, metal traces with a uniform line width can be obtained with a significantly reduced risk of metal bridging and higher manufacturing yield.

### BRIEF DESCRIPTION OF THE DRAWINGS

FIGS. 1A to 1C are schematic illustrations of structures resulting from steps in a conventional method of forming metal traces.

FIG. 2 is a flowchart of a method of forming metal traces according to an embodiment of the present invention.

FIGS. 3A to 3E schematically illustrate structures resulting from steps in a method of forming metal traces according to an embodiment of the present invention.

In these figures: 10, 100-substrate; 11, 101-metal layer; 11a, 101a-first metal barrier layer; 11b, 101b-aluminum layer; 11c, 101c-second metal barrier layer; 12, 102-DARC layer; 13, 103-BARC layer; 14, 104-photoresist layer; 14′, 104′-patterned photoresist layer.

### DETAILED DESCRIPTION

The ever-increasing integration of semiconductor devices is leading to more and more shrinkage of their overall size as well as of line width and space of metal traces in the semiconductor devices. In order to fabricate fine metal patterns in such highly-integrated semiconductor devices, shorter-wavelength exposure light sources are required to replace the conventional long-wavelength ones. For example, the fabrication of a fine pattern with a size of 1 mm, 90 nm or smaller requires a 248-nm krypton fluoride (KrF) excimer laser or a 93-nm argon fluoride (ArF) excimer laser to provide exposure light. Moreover, in order to achieve an even higher resolution of the metal pattern during exposure, a bottom anti-reflection coating (BARC) layer and/or a dielectric anti-reflective coating (DARC) layer is/are usually formed under the patterned photoresist layer, which can reduce or prevent reflections (which may lead to standing waves) during exposure. For example, the BARC layer can suppress the impact of back-diffracted light caused by sine waves and reflective notching during exposure, thus ensuring stable quality of the patterned photoresist layer.

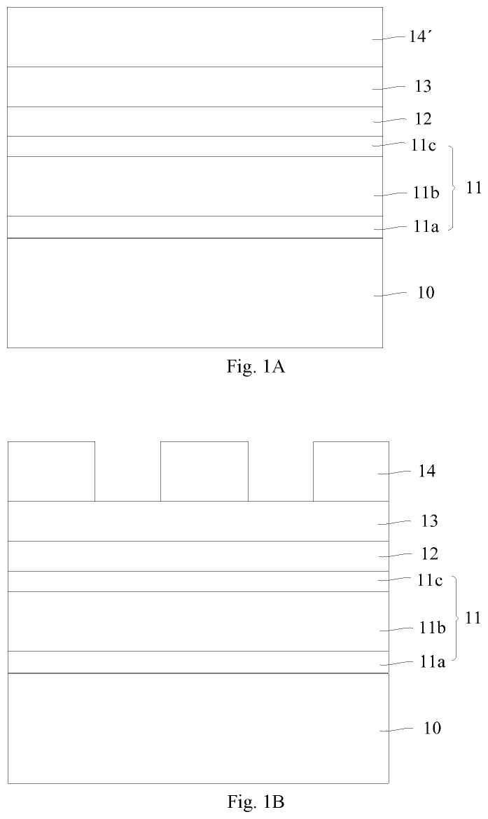

FIGS. 1A to 1C schematically show the formation of metal traces by patterning a metal layer with the aid of a BARC layer. As shown in FIG. 1A, a metal layer 11, as a precursor of the metal traces, is formed on a semiconductor substrate 10. The metal layer 11 consists of layers stacked one above another, including a first metal barrier layer 11a, an aluminum layer 11b and a second metal barrier layer 11c. A DARC layer 12 is then deposited on the metal layer 11, and the BARC layer 13 is in turn deposited on the DARC layer 12. After that, a photoresist layer 14′ is applied on the BARC layer 13, exposed with a photomask (not shown) defining the metal traces, and developed to pattern the photoresist layer 14, as shown in FIG. 1B. Afterward, a dry etching process is performed with the patterned photoresist layer 14 as a mask to remove a portion of the BARC layer 13, a portion of the DARC layer 12 and a portion of the metal layer 11, thereby forming the metal trace, as shown in FIG. 1C. The patterned photoresist layer 14 remaining on the BARC layer 13 is then removed by performing an ashing process.

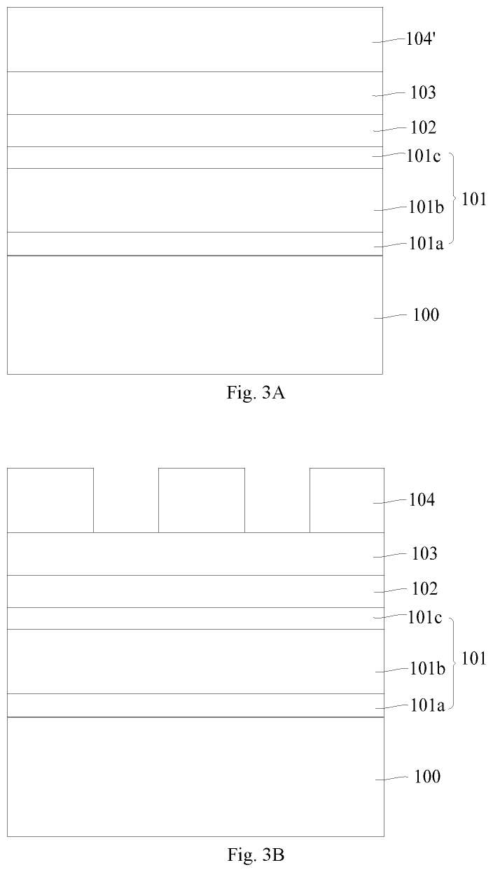

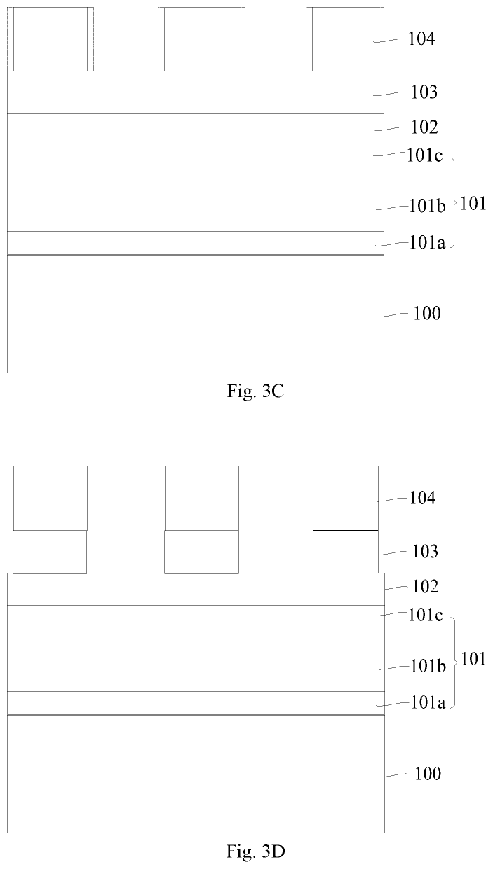

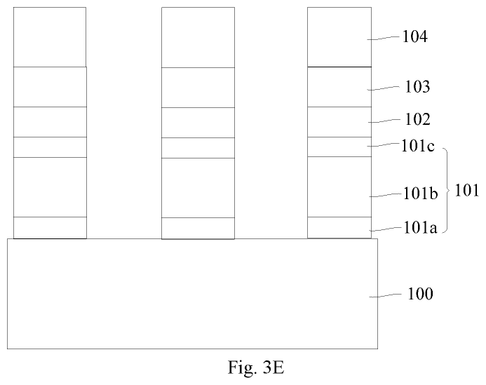

In the above approach for forming the metal traces, it is necessary to open the BARC layer 13, i.e., so-called “BARC Opening”, in which “openings” are formed in the BARC layer 13 by the etchant gas. As can be seen from FIG. 3D, the underlying DARC layer 12 will be exposed in the openings in the BARC layer 13, and the remainder of the BARC layer 13 will serve as a mask for the subsequent steps of the etching process. As a result, any defect in the shape of the BARC layer will be transferred to the various underlying layers (e.g., including the metal layer) to be etched. As such defects may be comparable to the desired critical dimension (CD) of the patterned photoresist layer 14, if the openings formed in the BARC layer 13 are narrower than those in the photoresist, then the openings etched in the underlying layers will also be narrower than the CD. Currently, BARC Opening is usually accomplished in one pass by a dry etching process using a mixture of HBr, O₂ and Cl₂ as the etchant gas. However, due to solid substances tend to result from the reaction of the gas mixture with the BARC layer 13, the formed openings in the BARC layer 13 are usually not evenly distributed and each opening is narrower at the bottom of the BARC layer. Consequently, the resulting metal traces are wider than desired and spaced apart at a pitch that is insufficient (e.g., <30 nm) to prevent the occurrence of metal bridging between adjacent metal traces. In serious cases, the entire metal interconnect that incorporates the metal traces may fail.

In view of this problem, in embodiments of the present invention, there is provided a method of forming metal traces, including: forming a BARC layer and a patterned photoresist layer both on a metal layer; trimming the patterned photoresist layer and concurrently partially etching away the BARC layer; and etching the metal layer with the trimmed patterned photoresist layer as a mask to form the metal traces. According to the invention, the BARC layer is etched concurrently with the trimming of the patterned photoresist layer, dispensing with the need for separate opening of the BARC layer, which may exert adverse impacts on the line width of the metal traces. Therefore, metal traces with a uniform line width can be obtained with a significantly reduced risk of metal bridging and higher manufacturing yield.

The invention will be better understood from the following detailed description of a few specific embodiments, which is to be read in connection with the accompanying drawings. Of course, the invention is not limited to these embodiments and all general substitutions known to those skilled in the art are intended to be also embraced in the scope of the invention.

In addition, for the sake of easier illustration, the drawings are presented in a schematic manner possibly not drawn to scale and possibly with exaggerations. This is not intended to be construed as limiting the scope of the invention.

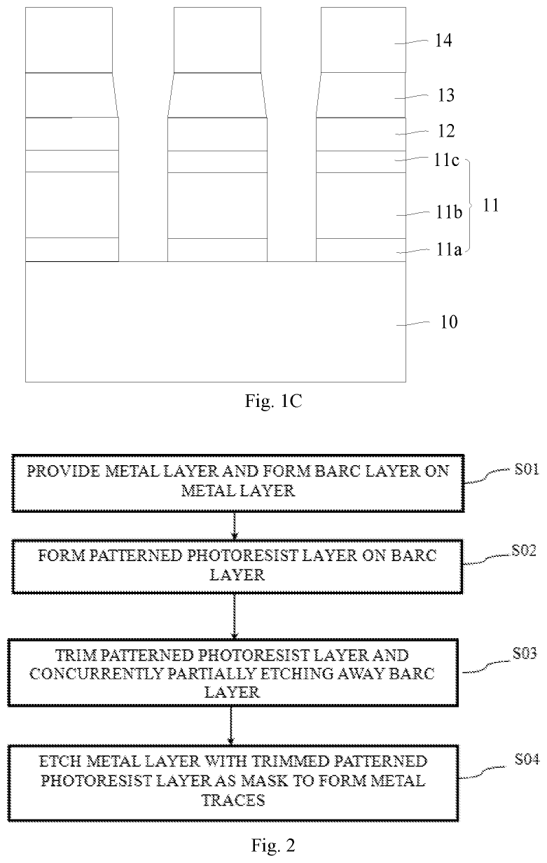

FIG. 2 is a flowchart of a method of forming metal traces according to an embodiment of the present invention. As shown in FIG. 2, the method includes the steps of:

S01) providing a metal layer and forming a BARC layer on the metal layer;

S02) forming a patterned photoresist layer on the BARC layer;

S03) trimming the patterned photoresist layer and concurrently partially etching away the BARC layer; and

S04) etching the metal layer with the trimmed patterned photoresist layer as a mask to form the metal traces.

FIGS. 3A to 3E schematically illustrate structures resulting from steps in a method of forming metal traces according to an embodiment of the present invention. The method will be described in greater detail below with reference to FIG. 2 as well as FIGS. 3A-3E.

At first, step S01 is performed, in which, as shown in FIG. 3A, a metal layer 101 is provided over the substrate 100. The metal layer 101 may be any metal layer in a metal interconnect being fabricated. That is, the metal layer may be provided on an interlayer dielectric layer which may be formed at any stage in the fabrication of the metal interconnect and in which through silicon vias (TSVs) will be formed. In this embodiment, the metal layer may be a lowermost metal layer (M1), which is closest to the substrate 100. Materials from which the substrate can be fabricated may include at least one of Si, Ge, SiGe, SiC, SiGeC, InAs, GaAs, InP and other III/V compound semiconductors. The substrate may be a multilayer structure formed of one or more of those semiconductor materials, a silicon-on-insulator (SOI) substrate, a strained silicon-on-insulator (SSOI) substrate, a strained silicon-germanium-on-insulator (SSGOI) substrate, a silicon-germanium-on-insulator (SGOI) substrate, a germanium-on-insulator (GOI) substrate or the like. As these are well known to those skilled in the art, further exemplification is unnecessary.

The metal layer 101 may be formed of aluminum (Al), copper (Cu), cobalt (Co), tungsten (W), iron (Ti), nickel (Ni), tantalum (Ta), titanium nitride (TiN), tantalum nitride (TaN), tungsten nitride (WN) or any combination thereof. The metal layer 101 may be formed by sequentially depositing a first metal barrier layer 101a, an aluminum layer 101b and a second metal barrier layer 101c over the surface of the substrate 100, for example, by sputtering, evaporation or chemical vapor deposition (CVD). That is to say, the metal layer 101 may consist of the stacked first metal barrier layer 101a, aluminum layer 101b and second metal barrier layer 101c. The first metal barrier layer 101a may be a 50-nm thick Ti layer, while the second metal barrier layer 101c may be a 49-nm thick TiN layer. The aluminum layer 101b may have a thickness of from 120 nm to 200 nm, such as 150 nm, 160 nm or 170 nm.

A DARC layer 102 and a BARC layer 103 may be then sequentially formed on the metal layer 101. The DARC layer 102 may be formed of dielectric material based on an oxide of silicon, silicon nitride or tetraethyl orthosilicate (TEOS). For example, the DARC layer 102 may be a SiO₂, SiON or SiN layer and have a thickness in the range of from 30 nm to 60 nm. The BARC layer 103 may be based on an organic or inorganic substance typically differing from the material of the underlying DARC layer 102. For example, the BARC layer 103 may be a TiN layer having a thickness between 20 nm and 50 nm.

Step S02 is then performed, in which a photoresist layer 104′ is formed on the BARC layer 103 and the photoresist layer 104′ is patterned to form a patterned photoresist layer 104. First of all, the photoresist layer 104′ may be formed on the BARC layer 103 by spinning and patterned by exposure and development to form photoresist layer 104 with a desired pattern of the metal traces 101, as shown in FIG. 3B.

Step S03 is then performed, in which the patterned photoresist layer 104 is trimmed and the BARC layer 103 is partially etched away. In FIG. 3C, the dashed boxes indicate the patterned photoresist layer prior to the trimming, while the solid boxes indicate the trimmed patterned photoresist layer. The trimming of the patterned photoresist layer 104 may be accomplished by a plasma etching process using Cl₂ and BCL₃ as the etchant at a Cl₂/BCL₃ flow rate ratio between 0.5 and 5, a radio frequency (RF) power level of 100-500 W and a bias voltage in the range of from 50 V to 200 V such as, for example, 50 V, 65 V, 100 V, 150 V, 200 V or the like. The etching process may last for a length of time taking into account both measurement-based post-development and post-etching conformity to the CD requirements. It has been experimentally confirmed that the bias affects the trimming in such a manner that a higher value of the bias voltage allows etchant ions to bomb the materials more vertically.

As shown in FIG. 3D, subsequent to the trimming of the patterned photoresist layer 104, the BARC layer 103 is subjected to primary etching, which may be accomplished by a dry etching process using, for example, Cl₂ and BCL₃ as the etchant at a Cl₂/BCL₃ flow rate ratio between 1 and 5, an RF power level of 100-500 W and a bias voltage in the range of from 200 V to 500 V. After the completion of the primary etching, the BARC layer 103 may be further subjected to over-etching, which can be accomplished by another dry etching process using, for example, Cl₂ and BCL₃ as the etchant at a Cl₂/BCL₃ flow rate ratio between 1 and 5, an RF power level of 100-500 W and a bias voltage in the range of from 200 V to 500 V. As a result, the pattern in the photoresist layer 104 is transferred into the DARC layer 102.

From the above description of the trimming of the patterned photoresist layer 104 as well as of the primary etching and over-etching of the BARC layer 103, it can be seen that, since the various etching processes are all biased, utilize similar etchant gases and are carried out under similar conditions, they can be preform on a single piece of etching equipment, meaning that the trimming of the patterned photoresist layer 104 is combined with the etching of the BARC layer 103. This dispenses with the need for BARC Opening immediately following the formation of the patterned photoresist layer 104, which may cause the problems of non-uniform line widths and hence possible metal bridging between adjacent metal traces. Moreover, combining the trimming of the patterned photoresist layer 104 with the etching of the BARC layer 103 can enhance process efficiency.

In another embodiment of the present invention, the BARC layer 103 may be implemented as an organic material such as an organic dielectric material such as fluorinated polyimide (FPI), polyarylene ether (PAE), fluorinated poly(arylethers) (FLARE), benzocyclobutene (BCB), amorphous carbon, SILK, MSQ, etc. or an organic polymeric material which is similar to photoresist but not photosensitive and can be applied by, for example, spinning. A dry etching process may be carried out to simultaneously trim and thus reduce the patterned photoresist layer 104 and partially remove and thus pattern the underlying BARC layer 103. The dry etching process may use a Cl₂/O₂ mixture, a HBr/O₂ mixture or the like as an etchant gas.

According to this embodiment, trimming and reducing the patterned photoresist layer 104 is helpful in obtaining a fine pattern when the line width and space of the metal trace are extremely small. Moreover, according to this embodiment, the trimming of the patterned photoresist layer 104 and the etching of the BARC layer 103 are accomplished in a single step. In this way, as separate etching of the BARC layer 103 is dispensed with, adverse impacts of BARK Opening on the line width of the metal traces can be avoided.

Subsequently, step S04 is performed, in which the metal layer 101 is etched to form the metal traces, with the trimmed patterned photoresist layer 104 serving as a mask. In other words, multiple grooves are formed in the metal layer 101, which partition the metal layer 101 into the metal traces. Specifically, with the patterned BARC layer 103 and the overlying trimmed patterned photoresist layer 104 both resulting from step S03 and residing on the DARC layer 102 serving as a mask, the metal layer 101 is etched to form therein multiple trenches which partition the metal layer 101 into the metal traces. For example, the etching of the metal layer 101 may include primary etching and over-etching, and the remainder of the patterned photoresist layer 104 on the BARC layer 103 may be removed by an ashing process. The etching of the metal layer 101 may be accomplished with a suitable conventional process which takes into account the actual thickness to be etched and actually required etching duration, and a detail description thereof is believed unnecessary.

As actually measured, metal traces formed by a conventional method in which, after a patterned photoresist layer was formed, BARC, DARC and metal layers were etched in one pass, had a line width wider than desired and thus an inadequate line-to-line space of about 30 nm, and the openings formed in the BARC layer were about 140 nm wide at the bottom of the BARC layer. By contrast, metal traces formed on the basis of a trimmed patterned photoresist layer in accordance with an embodiment of the present invention had a uniform line width and a wider space of 50 nm, and the BARC layer were 90 nm wide at the bottom of the BARC layer. These results demonstrate that, by partially etching away the BARC layer concurrently with the trimming of the patterned photoresist layer and then etching the DARC and metal layers with the trimmed patterned photoresist layer as a mask, metal traces with significantly improved line width uniformity, a wider space and a substantially reduced risk of metal bridging can be obtained, as discussed above.

In summary, the present invention provides a method of forming metal traces, including: forming a BARC layer and a patterned photoresist layer both on a metal layer; trimming the patterned photoresist layer and concurrently partially etching away the BARC layer; and etching the metal layer with the trimmed patterned photoresist layer as a mask to form the metal traces. According to the invention, the BARC layer is etched concurrently with the trimming of the patterned photoresist layer, dispensing with the need for separate opening of the BARC layer, which may exert adverse impacts on the line width of the metal traces. Therefore, metal traces with a uniform line width can be obtained with a significantly reduced risk of metal bridging and higher manufacturing yield.

While the invention has been described with reference to several preferred embodiments, it is not intended to be limited to these embodiments in any way. Any person of skill in the art may make various possible variations and changes to the disclosed embodiments without departing from the spirit and scope of the invention. Accordingly, any and all such simple variations, equivalent alternatives and modifications made to the foregoing embodiments without departing from the scope of the invention are intended to fall within the scope thereof

What is claimed is:

1. A method of forming metal traces, comprising:
providing a metal layer and forming a bottom anti-reflection coating (BARC) layer on the metal layer;
forming a patterned photoresist layer on the BARC layer;
trimming the patterned photoresist layer and concurrently etching away a partial thickness of the BARC layer; and
etching the metal layer with the trimmed patterned photoresist layer as a mask to form the metal traces.

2. The method of claim 1, wherein the metal layer comprises a first metal barrier layer, an aluminum layer and a second metal barrier layer, which are stacked together sequentially, and wherein the second metal barrier layer is closer to the BARC layer than the first metal barrier layer.

3. The method of claim 2, wherein each of the first and second metal barrier layers is a Ti/TiN stacked layer.

4. The method of claim 1, further comprising forming a dielectric anti-reflective coating (DARC) layer between the BARC layer and the metal layer.

5. The method of claim 4, wherein the BARC layer is an organic or inorganic layer, and wherein the DARC layer is a SiO₂, SiON or SiN layer.

6. The method of claim 5, wherein the BARC layer has a thickness of from 30 nm to 60 nm, and wherein the DARC layer has a thickness of from 20 nm to 50 nm.

7. The method of claim 1, wherein the patterned photoresist layer is trimmed by a dry etching process.

8. The method of claim 7, wherein an etchant gas used in the dry etching process comprises Cl₂ and BCL₃ and wherein a Cl₂/BCL₃ flow has a rate ratio between 0.5 and 5 and is performed at a radio frequency power level of 100-500 W and a bias voltage of 50-200 V.

9. The method of claim 1, wherein the etching of the BARC layer comprises primary etching and over-etching following the primary etching.

10. The method of claim 9, wherein the primary etching is accomplished by an etchant gas comprising Cl₂ and BCL₃ at a Cl₂/BCL₃ flow rate ratio between 1 and 5, a radio frequency power level of 100-500 W and a bias voltage of 200-500 V.

11. The method of claim 9, wherein the over-etching is accomplished by an etchant gas comprising Cl₂ and BCL₃ at a Cl₂/BCL₃ flow rate ratio between 1 and 5, a radio frequency power level of 100-500 W and a bias voltage of 200-500 V.
